(19) United States
(12) Patent Application Publication
(10) Pub. No.: US 2024/0283179 A1
(43) Pub. Date: Aug. 22, 2024

(54) Battery Connector

(71) Applicant: Google LLC, Mountain View, CA (US)

(72) Inventors: David Wang, San Jose, CA (US); Chien-Yueh Tung, Hsinchu County (TW); Hsi Pin Chuang, New Taipei City (TW); James Robert Lim, Mountain View, CA (US)

(73) Assignee: Google LLC, Mountain View, CA (US)

(21) Appl. No.: 18/638,231

(22) Filed: Apr. 17, 2024

Related U.S. Application Data
(60) Provisional application No. 63/633,947, filed on Apr. 15, 2024.

(51) Int. Cl. H01R 12/79; H01R 43/26; H05K 1/02; H05K 1/18

(52) U.S. Cl. CPC H01R 12/79; H05K 1/028; H05K 1/189; H01R 43/26; H05K 2201/10037; H05K 2201/10189; H05K 2201/10522; H05K 2201/10545

(57) ABSTRACT

The disclosure describes a battery connector that includes a bendable axis configured to enable a first portion of the battery connector to be electrically connected to a corresponding connector prior to connecting a second portion. A flexible printed circuit may connect the first portion to the second portion and the bendable axis may be located along the flexible printed circuit. A hinge may connect the first portion to the second portion and enable the first portion to bend with respect to the second portion. A flexible printed circuit connected to the battery connector may enable the battery connector to wrap around an edge of a printed circuit board so that the first portion of the battery connector is connected to a first side of the printed circuit board and the second portion of the battery connector is connected to a second side of the printed circuit board.

### CROSS-REFERENCE TO RELATED APPLICATION(S)

This application claims the benefit of U.S. Provisional Patent Application Ser. No. 63/633,947 filed on Apr. 15, 2024, the disclosure of which is incorporated by reference herein in its entirety.

### SUMMARY

This document describes a battery connector that includes a bendable axis. The bendable axis is configured to enable a first portion of the battery connector to be electrically connected to a corresponding connector prior to a second portion of the battery connector being connected to the corresponding connector. Connecting the first portion of the battery connector prior to connecting the second potion may ensure that the battery connector is grounded before a high voltage from a battery, or other source of electricity, is transferred to the corresponding connector, which may prevent or reduce potential damage to sensitive components connected to the corresponding connector.

Various mechanisms are disclosed that enable a battery connector to be bendable about an axis. In one example, a first portion of the battery connector is connected to a second portion of the battery connector via a flexible printed circuit. The flexible printed circuit may enable the first portion of the battery connector to bend about an axis with respect to the second portion of the battery connector. The first portion of the battery connector may include negative pins, or grounding pins, and the second portion of the battery connector may include positive pins. The bendable axis of the flexible circuit may enable the grounding pins (e.g., negative pins) of the battery connector to be electrically connected to a corresponding connector prior to the positive pins of the battery connector being connected to the corresponding connector.

In aspects, a hinge may be used to connect a first portion of a battery connector to a second portion of the battery connector. The hinge enables the battery connector to bend about the hinge. The hinge may enable the grounding pins (e.g., negative pins) of the first portion to be electrically connected to a corresponding connector prior to connecting the positive pins of the second portion.

In some aspects, a battery connector is disclosed that includes a first portion of the battery connector that is connected to a second portion of the battery connector via a flexible printed circuit. The flexible printed circuit is configured to electrically connect the first portion and the second portion of the battery connector to a source of electricity, such as a battery. The flexible printed circuit may be configured to have a first bendable axis and a second bendable axis. The flexible printed circuit includes a length of printed flexible board between the two bendable axes, and the first bendable axis, the second bendable axis, and the length of the printed flexible board are configured to enable the battery connector to be connected around an edge of a printed circuit board, a multi-layer board, a flexible printed circuit board, or the like.

In aspects, the first bendable axis is configured to enable the first portion of the battery connector to be electrically connected to a first side of a printed circuit board. The second bendable axis is configured to enable the second portion of the battery connector to be electrically connected to a second side of the printed circuit board. These two bendable axes enable the battery connector to be located at an edge of the printed circuit board. The length of the flexible printed circuit between the two axes enables the battery connector to wrap around the edge of the printed circuit board. The first portion of the battery connector may include both positive and negative pins, and the second portion of the battery connector may also include both positive and negative pins and, thus, be redundant to the first portion of the battery connector.

In example implementations, an apparatus includes a battery connector including a first portion connected to a second portion. At least one negative pin is connected to the first portion and at least one positive pin is connected to the second portion. The battery connector is configured to bend about an axis located between the first portion and the second portion.

### BRIEF DESCRIPTION OF DRAWINGS

Apparatuses of and techniques for a battery connector are described with reference to the following drawings. The same numbers are used throughout the drawings to reference like features and components:

FIG. 1 illustrates an example battery connector that may bend about an axis;

FIG. 2 illustrates an example battery connector that is configured so that a first portion of the battery connector may be connected to a corresponding connector prior to a second portion of the battery connector being connected to the corresponding connector;

FIG. 3 illustrates an example battery connector that includes a hinge configured so that a first portion of the battery connector may be connected to a corresponding connector prior to a second portion of the battery connector being connected to the corresponding connector;

FIG. 4 illustrates an example battery connector that is configured to wrap around a printed circuit board; and

FIG. 5 illustrates an example battery connector that is configured to wrap around a printed circuit board.

### DETAILED DESCRIPTION

### Overview

Board-to-board battery connectors often include a plug configured to be inserted into a socket to connect a battery, or other source of electricity, to the components of an electrical device. The connection of the two board-to-board battery connectors may often be a blind connection, meaning the view of the user may be blocked by a board, or other component, during the mating process of the two battery connectors. A blind connection may cause the user to need to make the connection by feel, rather than by sight, which can result in a potential misalignment between the two connectors. Misalignment of two battery connectors may result in the premature application of a high battery voltage to sensitive components before the battery connection is properly grounded, which can potentially damage the sensitive components. A flexible battery connector may enable a battery connector to have the grounding pins connected prior to the power pins, which may overcome or at least reduce the potential risk of misaligned battery connectors.

Rigid battery connectors that are not bendable may crack and/or become damaged due to repeated connection to and removal from a corresponding connector. Mechanical shock and/or impact to an electronic device may also result in damage to a rigid battery connector of the electronic device. Damage to a battery connector may result in high impedance, reduced device runtime, and/or loss of device power. A flexible battery connector may overcome or at least reduce the disadvantages of potential damage to a battery connector due to mechanical shock, impact, or repeated coupling and decoupling of battery connectors.

The charging of a battery may result in the application of a high current through a battery connector to enable rapid or fast charging of the battery. The application of a high current may result in significant thermal buildup of the battery connectors and/or adjacent components, which may result in the potential damage of the adjacent components or the battery connectors. A flexible battery component may be configured to wrap around an edge of a printed circuit board or the like to distribute the potential thermal buildup to both sides of the printed circuit board rather than just a single side of the printed circuit board.

There are many ways that a battery connector can become damaged, rendering useless an electronic device configured to use the battery connector. Once damaged, the battery connector typically will need to be repaired or replaced for continued use of the electronic device. A flexible battery connector that includes a first portion and a redundant second portion may overcome or at least reduce these disadvantages.

This document describes a battery connector that includes a bendable axis configured to enable a first portion of the battery connector to be electrically connected to a corresponding connector prior to electrically connecting a second portion of the battery connector to the corresponding connector. Connecting a first portion of a battery connector prior to connecting a second portion of the battery connector may ensure that the battery connector is grounded before a high voltage from a battery is transferred to the corresponding connector. The bendable axis and sequential connection process may prevent or reduce potential damage to sensitive components connected to the corresponding connector.

Various mechanisms disclosed herein enable a battery connector to be bendable about an axis. For example, a flexible printed circuit may connect a first portion of a battery connector to a second portion of the battery connector. The flexible printed circuit enables the first portion of the battery connector to bend about an axis with respect to the second portion of the battery connector. Negative pins (e.g., grounding pins) connected to the first portion of the battery connector may be connected first to a corresponding connector because the battery connector may bend about the axis. After connecting the negative pins of the first portion, positive pins connected to the second portion may then be connected to the corresponding connector. The flexible printed circuit and sequential connection process may ensure that the battery connectors are grounded prior to the application of a high current through the mated battery connectors.

In aspects, a hinge is used to connect a first portion of a battery connector to a second portion of the battery connector. The hinge enables the battery connector to bend about the hinge to enable grounding pins (e.g., negative pins) of the first portion to be electrically connected to a corresponding connector prior to connecting the positive pins of the second portion to the corresponding connector.

In some aspects, a battery connector is disclosed that includes a first portion of the battery connector that is connected to a second portion of the battery connector via a flexible printed circuit. The flexible printed circuit is configured to electrically connect the first and second portions of the battery connector to a source of electricity, such as a battery. The flexible printed circuit includes a first bendable axis and second bendable axis configured to enable the battery connector to wrap around an edge of a printed circuit board, a multi-layer board, a flexible printed circuit board, or the like. Because the battery connector can wrap around an edge of a printed circuit board, the first portion of the battery connector may be connected to a first side of the printed circuit board and the second portion of the battery connector may be connected to a second side of the printed circuit board. Such multi-side connection to the printed circuit board can distribute potential thermal buildup between the two sides of the printed circuit board instead of having the potential thermal buildup on a single side of the printed circuit board.

In aspects, the first bendable axis is configured to enable the first portion of the battery connector to be electrically connected to a first side of a printed circuit board. The second bendable axis is configured to enable the second portion of the battery connector to be electrically connected to a second side of the printed circuit board. These two bendable axes enable the battery connector to be located at an edge of the printed circuit board. The flexible printed circuit includes a length that enables the battery connector to wrap around the edge of the printed circuit board. The first portion and the second portion of the battery connector may be redundant. In other words, the first portion of the battery connector may include both positive and negative pins and the second portion of the battery connector may also include both positive and negative pins. In this implementation, the battery connector may still be able to connect to an electrical device in the event that the first portion or the second portion of the battery connector is damaged.

These and other implementations are described in further detail herein.

### Example Apparatuses and Systems

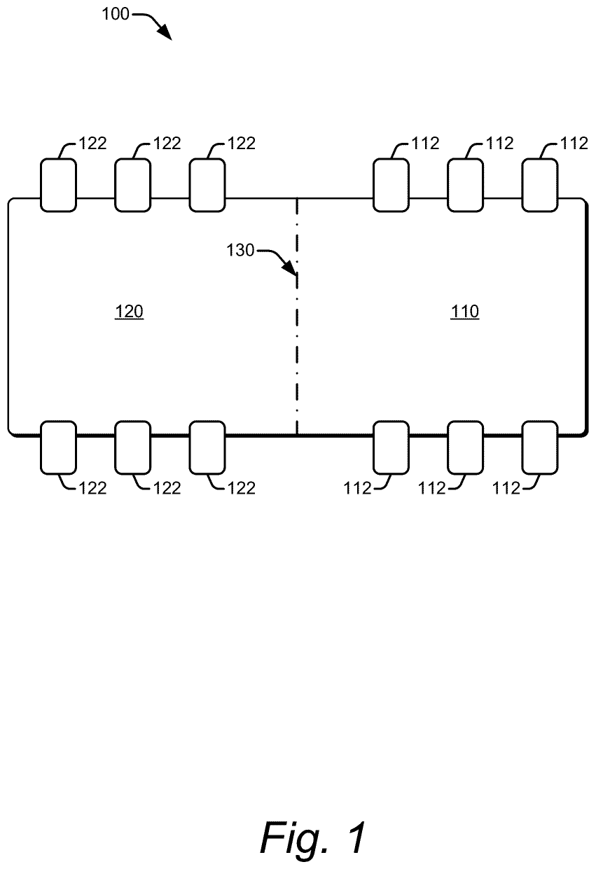

FIG. 1 illustrates an example apparatus, or battery connector 100, which includes a first portion 110 connected to a second portion 120. The first portion 110 may be directly connected to the second portion 120 as shown in FIG. 1. Alternatively, the first portion 110 may be connected to the second portion 120 by one or more intermediary components as discussed herein. In an implementation, the first portion 110 and the second portion 120 are rigid. The first portion 110 of the battery connector 100 includes one or more negative pins 112 that are configured to electrically connect to electrical contacts or electrical pins connected to a corresponding electrical connector. Likewise, the second portion 120 of the battery connector 100 includes one or more positive pins 122 that are configured to electrically connect to electrical contacts or electrical pins connected to a corresponding electrical connector. The battery connector 100 is configured to bend about a bendable axis 130 located between the first portion 110 and the second portion 120.

The bendable axis 130 enables the negative pins 112 of the first portion 110 of the battery connector 100 to be connected to a corresponding electrical connector prior to connecting the positive pins 122 of the second portion 120 of the battery connector 100 to the corresponding electrical connector. The bendable axis 130 of the battery connector 100 may allow the mating of the ground pins (e.g., the negative pins 112) to be a guiding feature of connecting the battery connector 100 to the corresponding connector. Connecting the negative pins 112 prior to connecting the positive pins 122 may reduce the risk of damage to sensitive components connected to the corresponding connector by the application of a high battery voltage or high current before the battery connector 100 is grounded via the negative pins 112.

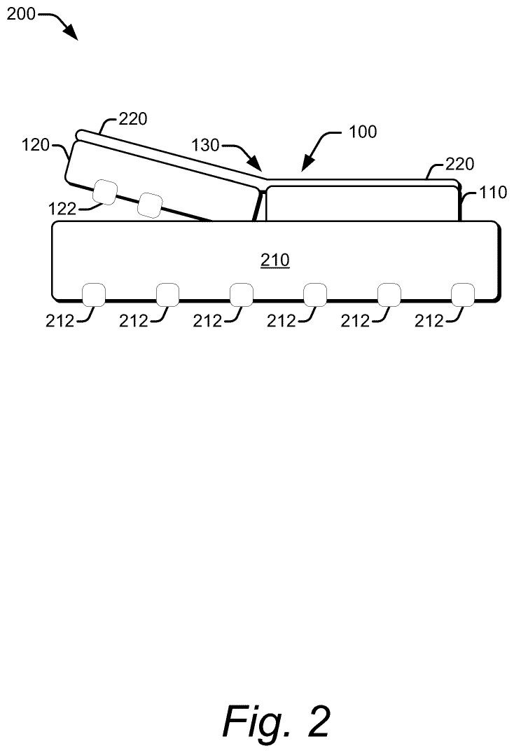

FIG. 2 illustrates a system 200 that includes an example of the battery connector 100 being connected to a corresponding electrical connector 210. The corresponding connector 210 includes a plurality of electrical pins 212 configured to electrically connect the corresponding connector 210 to a printed circuit board, multi-layer board, flexible printed circuit, or the like. The example battery connector 100 includes the first portion 110 connected to the second portion 120 via a flexible printed circuit 220.

The battery connector 100 is configured to bend about the bendable axis 130 located along the flexible printed circuit 220. The bendable axis 130 enables the negative pins 112 (not shown in FIG. 2) of the first portion 110 of the battery connector 100 to be inserted into and electrically connected to the corresponding connector 210, as shown in FIG. 2. Afterwards, the positive pins 122 of the second portion 120 of the battery connector 100 may be inserted into and electrically connected to the corresponding connector 210. As discussed herein, connecting the negative pins 112 prior to connecting the positive pins 122 may reduce the risk of damage to sensitive components by the application of a high battery voltage before the battery connector 100 is grounded via the negative pins 112. When the battery connector 100 is fully inserted into, or connected, to the corresponding connector 210, the negative and positive pins 112, 122 of the battery connector 100 are electrically connected to the electrical pins 212 of the corresponding connector 210.

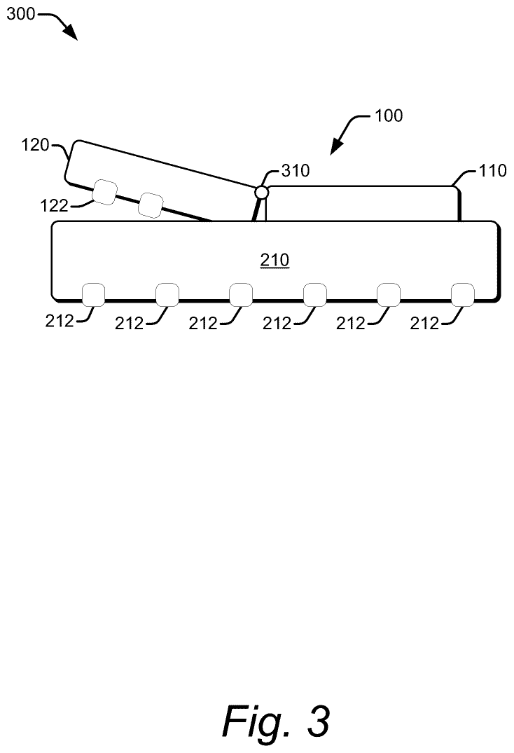

FIG. 3 illustrates a system 300 that includes an example of the battery connector 100 being connected to the corresponding connector 210 that includes a plurality of electrical pins 212 configured to electrically connect the corresponding connector 210 to a printed circuit board, multi-layer board, flexible printed circuit, or the like. The example battery connector 100 includes a hinge 310 connected to the first portion 110 and the second portion 120 of the battery connector 100. In one implementation, the hinge 310 may include a first plate connected to a second plate with a pin positioned between the plates to enable the first plate and second plate to bend about the pin with respect to each other. The first plate is connected to the first portion 110 of the battery connector 100 with the second plate connected to the second portion 120 of the battery connector 100. In another implementation, the hinge may be an integral hinge that includes a thinned, or cut, portion connected between two rigid pieces. The thinned portion enables the two rigid pieces to bend about the thinned portion with respect to each other. One of the rigid pieces is connected to the first portion 110 of the battery connector 100 with the other rigid piece being connected to the second portion 120 of the battery connector 100.

The bendable axis 130 of the battery connector 100 (shown in FIG. 1) is provided by and aligns with the hinge 310. The hinge 310 enables the first portion 110 and the second portion 120 of the battery connector 100 to bend about the hinge 310. As shown in FIG. 3, the hinge 310 enables the negative pins 112 (not shown in FIG. 2) of the first portion 110 to be electrically connected to the corresponding connector 210 prior to the positive pins 122. After the connection of the negative pins 112, the positive pins 122 of the second portion 120 may electrically connected to the corresponding connector 210. As discussed herein, connecting the negative pins 112 prior to connecting the positive pins 122 may ensure that the battery connector 100 is grounded prior to power be applied to the corresponding electrical connector 210.

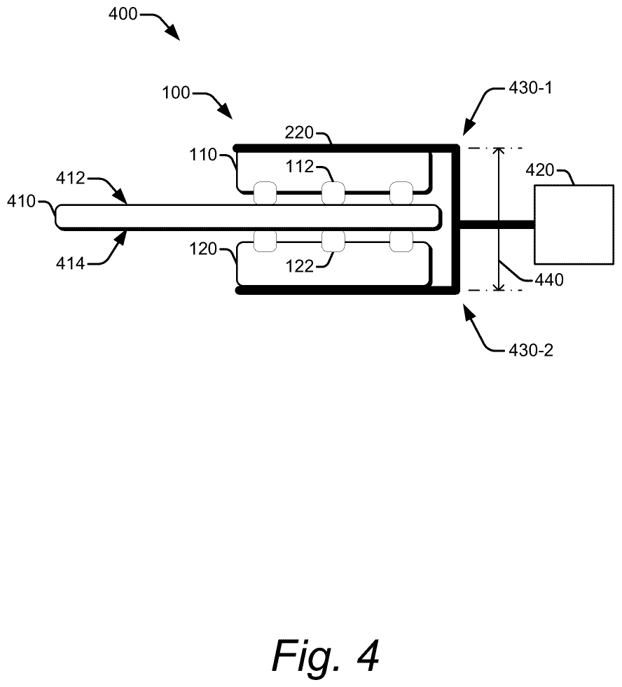

FIG. 4 illustrates a system 400 that includes an example of the battery connector 100 being connected to electrical contacts, or a corresponding connector, on each side 412, 414 of a printed circuit board 410. The printed circuit board 410 may be a printed circuit board, multi-layer board, flexible printed circuit, or the like. In the illustrated example, the battery connector 100 includes the first portion 110 connected to the second portion 120 via the flexible printed circuit 220. The one or more negative pins 112 of the first portion 110 are configured to electrically connect to pins in a corresponding electrical connector on a first side 412 of the printed circuit board 410. Likewise, the one or more positive pins 122 of the second portion 120 are configured to electrically connect to pins a corresponding electrical connector on a second side 414 of the printed circuit board 410. The flexible printed circuit 220 is configured to electrically connect the first portion 110 of the battery connector 100 to an electrical source 420, which may be a battery pack. Likewise, the flexible printed circuit 220 is configured to electrically connect the second portion 120 of the battery connector 100 to the electrical source 420.

The flexible printed circuit 220 is configured to bend about a first axis 430-1 and to bend about a second axis 430-2. The flexible printed circuit 220 includes a length 440 between the first axis 430-1 and the second axis 430-2. Together, the length 440 of the flexible printed circuit 220, the first axis 430-1, and the second axis 430-2 are configured to enable the battery connector 100 to wrap around an edge of the printed circuit board 410, as shown in FIG. 4.

The first portion 110 of the battery connector 100 is connected to the flexible printed circuit 220 that is configured to bend about the first axis 430-1 to enable the first portion 110 to engage and electrically connect to the first side 412 of the printed circuit board 410. The second portion 120 of the battery connector 100 is connected to the flexible printed circuit 220 that is configured to bend about the second axis 430-2 to enable the second portion 120 to engage and electrically connect to the second side 414 of the printed circuit board 410. Such an architecture of the length 440 of the flexible printed circuit 220, the first axis 430-1, and the second axis 430-2 enable the battery connector 100 to be located at an edge of the printed circuit board 410, which may provide thermal distribution to both the first side 412 and the second side 414 of the printed circuit board 410.

The overall length of the flexible printed circuit 220 may be varied to enable the battery connector 100 to engage corresponding electrical connectors on the first side 412 and the second side 414 of the printed circuit board 410. For example, increasing the overall length of the flexible printed circuit 220 enables the battery connector 100 to engage corresponding electrical connectors that are positioned farther inward from the edge of the printed circuit board 410. Likewise, varying a distance of the length 440 of the flexible printed circuit 220 between the first axis 430-1 and the second axis 430-2 would enable the battery connector 100 to wrap around printed circuit boards 410 having varying thickness. For example, increasing the distance of the length 440 of the flexible printed circuit 220 would enable the battery connector 100 to wrap around a printed circuit board 410 having a greater thickness while decreasing the distance of the length 440 of the flexible printed circuit 220 would enable the battery connector 100 to wrap around a printed circuit board 410 having a reduced thickness.

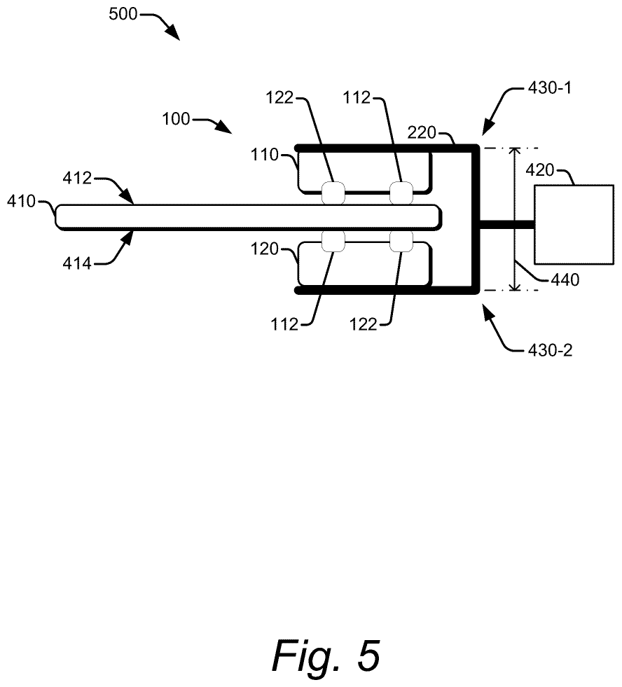

FIG. 5 illustrates a system 500 that includes an example of the battery connector 100 being connected to electrical contacts, or a corresponding connector, on both sides 412, 414 of a printed circuit board 410. A flexible printed circuit 220 connects the first portion 110 of the battery connector 100 to the second portion 120 of the battery connector 100. The first portion 110 includes one or more negative pins 112 and one or more positive pins 122 configured to electrically connect to pins in a corresponding electrical connector. Likewise, the second portion 120 includes one or more negative pins 112 and one or more positive pins 122 configured to electrically connect to pins in a corresponding electrical connector. The flexible printed circuit 220 is configured to electrically connect the pins 112, 122 of the first portion 110 of the battery connector 100 to an electrical source 420, which may be a battery pack. Likewise, the flexible printed circuit 220 is configured to electrically connect the pins 112, 122 of the second portion 120 of the battery connector 100 to the electrical source 420.

The flexible printed circuit 220 is configured to wrap the battery connector 100 about an edge of the printed circuit board 410. The flexible printed circuit 220 includes a first bendable axis 430-1 and a second bendable second axis 430-2 with a length 440 of flexible printed circuit 220 between the first bendable axis 430-1 and the second bendable axis 430-2. The configuration of the length 440 of the flexible printed circuit 220, the first axis 430-1, and the second axis 430-2 enable the battery connector 100 to wrap around an edge of the printed circuit board 410 as shown in FIG. 5. The first bendable axis 430-1 of the flexible printed circuit enables the first portion 110 of the battery connector 100 to engage and electrically connect to an electrical connector on the first side 412 of the printed circuit board 410. The second bendable axis 430-2 of the flexible printed circuit enables the second portion 120 of the battery connector 100 to engage and electrically connect to an electrical connector on the second side 414 of the printed circuit board 410.

The battery connector 100 may provide redundancy as both the first portion 110 and the second portion 120 of the battery connector 100 include one or more negative pins 112 and one or more positive pins 122. In the event that the first portion 110 of the battery connector 100 is damaged or disconnected, the electrical connection between the printed circuit board 410 and the electrical source 420 may be maintained by the second portion 120 of the battery connector 100. Likewise, the first portion 110 of the battery connector 100 may maintain the electrical connection with the printed circuit board 410 if the second portion 120 of the battery connector 100 is damaged or disconnected and the first portion 110 remains undamaged and connected.

### Example Aspects and Implementations of a Battery Connector

In the following, some example aspects and implementations are described:

Example aspect 1. An apparatus comprising: a battery connector including a first portion connected to a second portion; at least one negative pin connected to the first portion; and at least one positive pin connected to the second portion, the battery connector configured to bend about an axis located between the first portion and the second portion.

Example aspect 2. The apparatus of example aspect 1, wherein the first portion and the second portion are configured to enable the at least one negative pin to be connected to a corresponding connector prior to the at least one positive pin being connected to the corresponding connector and wherein the first portion and the second portion are rigid.

Example aspect 3. The apparatus of example aspect 1 or example aspect 2, further comprising: a hinge, wherein the first portion of the battery connector is connected to the second portion of the battery connector via the hinge.

Example aspect 4. The apparatus of example aspect 1 or example aspect 2, further comprising: a flexible printed circuit, wherein the first portion is connected to the second portion via the flexible printed circuit and wherein the axis is located along the flexible printed circuit.

Example aspect 5. The apparatus of example aspect 1, further comprising: a flexible printed circuit, wherein the first portion is connected to the second portion via the flexible printed circuit and wherein the axis is located along the flexible printed circuit.

Example aspect 6. The apparatus of example aspect 5, wherein the axis is a first axis and the battery connector is configured to additionally bend about a second axis located between the first portion and the second portion.

Example aspect 7. The apparatus of example aspect 6, wherein the first axis and the second axis are located along the flexible printed circuit.

Example aspect 8. The apparatus of example aspect 7, wherein the first axis is configured to enable the at least one negative pin to connect to a first corresponding connector on a first side of a printed circuit board and the second axis is configured to enable the at least one positive pin to connect to a second corresponding connector on a second side of the printed circuit board.

Example aspect 9. The apparatus of example aspect 6, further comprising at least one positive pin connected to the first portion of the battery connector and at least one negative pin connected to the second portion of the battery connector.

Example aspect 10. The apparatus of example aspect 9, wherein the first axis is configured to enable the first portion of the battery connector to connect to a first corresponding connector on a first side of a printed circuit board and the second axis is configured to enable the second portion of the battery connector to connect to a second corresponding connector on a second side of the printed circuit board.

Example aspect 11. The apparatus of example aspect 5, wherein the first portion and the second portion are rigid.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Although implementations for a battery connector have been described in language specific to certain features and/or methods, the subject of the appended claims is not necessarily limited to the specific features or methods described. Rather, the specific features and methods are disclosed as example implementations for a battery connector.

What is claimed is:

1. An apparatus comprising:
a battery connector including a first portion connected to a second portion;
at least one negative pin connected to the first portion; and
at least one positive pin connected to the second portion, the battery connector configured to bend about an axis located between the first portion and the second portion.

2. The apparatus of claim 1, wherein the first portion and the second portion are configured to enable the at least one negative pin to be connected to a corresponding connector prior to the at least one positive pin being connected to the corresponding connector and wherein the first portion and the second portion are rigid.

3. The apparatus of claim 2, further comprising:
a hinge, wherein the first portion of the battery connector is connected to the second portion of the battery connector via the hinge.

4. The apparatus of claim 2, further comprising:
a flexible printed circuit, wherein the first portion is connected to the second portion via the flexible printed circuit and wherein the axis is located along the flexible printed circuit.

5. The apparatus of claim 1, further comprising:
a flexible printed circuit, wherein the first portion is connected to the second portion via the flexible printed circuit and wherein the axis is located along the flexible printed circuit.

6. The apparatus of claim 5, wherein the axis is a first axis and the battery connector is configured to additionally bend about a second axis located between the first portion and the second portion.

7. The apparatus of claim 6, wherein the first axis and the second axis are located along the flexible printed circuit.

8. The apparatus of claim 7, wherein the first axis is configured to enable the at least one negative pin to connect to a first corresponding connector on a first side of a printed circuit board and the second axis is configured to enable the at least one positive pin to connect to a second corresponding connector on a second side of the printed circuit board.

9. The apparatus of claim 6, further comprising at least one positive pin connected to the first portion of the battery connector and at least one negative pin connected to the second portion of the battery connector.

10. The apparatus of claim 9, wherein the first axis is configured to enable the first portion of the battery connector to connect to a first corresponding connector on a first side of a printed circuit board and the second axis is configured to enable the second portion of the battery connector to connect to a second corresponding connector on a second side of the printed circuit board.

11. The apparatus of claim 5, wherein the first portion and the second portion are rigid.
